(19) United States
(12) Patent Application Publication
(10) Pub. No.: US 2011/0283577 A1
(43) Pub. Date: Nov. 24, 2011

(54) MIRROR UNIT COMPRISING A MIRROR SURFACE AND A LIGHTING UNIT

(75) Inventors: Hugo J. Cornelissen, Waalre (NL); Ferry Zijp, Nuenen (NL); Marcus J. Van Bommel, Waalre (NL); Petrus J. H. Seuntiens, Hoogeloon (NL); Marten Sikkens, Nuenen (NL); Willem P. Van Hoof, Horst (NL)

(73) Assignee: KONINKLIJKE PHILIPS ELECTRONICS N.V., EINDHOVEN (NL)

(21) Appl. No.: 13/146,834

(22) PCT Filed: Jan. 25, 2010
(86) PCT No.: PCT/IB10/50304

§ 371 Date: Jul. 28, 2011

(30) Foreign Application Priority Data
Jan. 30, 2009 (EP) 09151711.0

(51) Int. Cl. G09F 13/16; H01L 33/02; G08B 21/00; F21V 5/00

(52) U.S. Cl. 40/582; 362/235; 362/555; 340/686.6

(57) ABSTRACT

The invention provides a mirror unit having a mirror unit front with a mirror surface and having a lighting unit comprising a plurality of light sources and a lenticular lens array. The light sources and the lenticular lens array are arranged to provide mirror unit light in a space in front of the mirror unit front.

### FIELD OF THE INVENTION

The invention relates to a mirror unit comprising a mirror surface and a lighting unit. The invention also relates to the use of the mirror unit as fitting room mirror, particularly to display information by at least part of the mirror unit light generated by the lighting unit of the mirror unit.

### BACKGROUND OF THE INVENTION

Mirrors are used in shops, in offices, at home, etc. in (full) bathrooms, fitting rooms, but also in hallways, stairways, lobbies, etc.

Often, mirrors and lighting are adjusted to each other or are combined in one unit.

DE19703913 for instance describes a support device formed by a support tube arranged at least partly rotatably on a cabinet, on which a lighting component is fixed. The lighting component is securable onto the support tube, and is firmly connected to a clamp-type basic part which in the area of a hole engages around the support tube. The support tube encases the electrical cables for the lighting component. The support tube is located so as to be rotatable at both ends. It connects two side components of the cabinet to one another, the upper areas of which form a bearing for the support tube.

DE3218416 describes a working mirror for arrangement in front of a client's seat, which mirror is intended for use in carrying out work, in particular hairdressing work, preferably by one attendant, the working mirror having a mirror surface in which within an observation range at least that part of the client being treated can be observed by the client and, if appropriate, also by the attendant, the working mirror having at least one display region lying outside the observation range, in which region the mirror surface is designed as a transparent looking glass with rear lighting, and a lighting device which can optionally be switched on is provided behind the mirror surface, and information means can be mounted which become visible for the client when they are lit by the lighting device.

U.S. Pat. No. 6,801,371 describes a multi-functional dressing mirror applied to a portable case body for containing a plane mirror inside; in addition, the outer covering, a convex mirror made from materials showing the effect of light transmission, can be used to magnify a user's reflection while she/he is staring at the plane mirror. It would be possible for the user to directly use either the plane mirror or the convex mirror while the case lid is opened.

US 2008278935 describes a mirror lamp which includes a mirror lamp body, a hanging plate mounted on the mirror lamp body, and a wall attachment plate detachably combined with the hanging plate. The hanging plate is hung on the wall attachment plate to attach the mirror lamp body to a wall so that the mirror lamp functions as a wall lamp or a night lamp. In addition, the hanging plate is detachable from the wall attachment plate, so that the mirror lamp body is operated individually to provide an illuminating function and to provide a dressing or make-up function. Further, when the mirror lamp body is operated individually, the base of the mirror lamp body is mountable on a table so that the mirror lamp functions as a table lamp. The mirror lamp may further comprise a battery box mounted on the hanging plate and received in the receiving chamber of the base of the mirror lamp body, at least one rechargeable battery being accommodated in the battery box and electrically connected to the light emitting members to supply electric power to the light emitting members.

### SUMMARY OF THE INVENTION

A disadvantage of some of the prior art systems providing a mirror and lighting is that the illumination, such as for instance in fitting rooms, may not be optimal. A further disadvantage of prior art systems is that these systems do not have the ability to provide information and/or a tangible and intuitive user interface for a user, whereas it appears that there is a need for such features.

Hence, it is an aspect of the invention to provide an alternative mirror unit, which preferably further obviates at least partly one or more of the above-described drawbacks.

Therefore, the invention provides a mirror unit comprising:

a. a mirror unit front comprising a mirror surface;

b. a lighting unit comprising a plurality of light sources and a lenticular lens array arranged to provide mirror unit light in a space in front of the mirror unit front (also indicated as “mirror front”).

The lenticular lenses allow directing the light from the lighting unit in desired directions, such as in a direction substantially perpendicular to the mirror surface and/or at an angle relative to a normal to the mirror surface. For instance, the angle(s) (to such a normal) may be selected to reduce or prevent glare and/or may be selected to illuminate one or more of a wall, a ceiling and a floor. An advantage of using a lenticular lens array may also be that rather thin and cheap lenses may be used, which may allow designing mirror units that are relatively thin, as compared to some prior art mirror units, and controlling production costs. The term “lenticular lens array” may also include a plurality of lenticular lens arrays.

Preferably, the light sources of the lighting unit are selected from the group consisting of LEDs (light emitting diodes) and OLEDS (organic light emitting diodes), although it is not excluded that in other embodiments, incandescent and/or luminescent lamps are applied, alternatively or additionally to the LEDs and/or OLEDs. As will be clear to the person skilled in the art, also combinations of two or more types of light sources may be applied.

In a preferred embodiment, the plurality of light sources comprises a plurality of OLEDs. In yet another embodiment, the lighting unit comprises a light guide and one or more light sources, preferably one or more solid state LEDs, arranged to emit light into the light guide, wherein the light guide comprises a plurality of light extraction regions, and wherein the one or more light sources, the light guide, the plurality of light extraction regions, and the lenticular lens array are arranged to provide mirror unit light in the space in front of the mirror unit front. The light extraction regions can be artificial irregularities in the light guide, such as cavities, indentations, protrusions, micro-prisms, micro-grooves or other structures, that induce at least part of the incoupled mirror light to exit the waveguide (in the direction of one or more lenticular lenses).

It is also possible that the light guide comprises a plurality of phosphor dot regions, where blue, violet or UV LED light is converted to for instance yellow and/or other colors. Therefore, in an embodiment, the invention also provides an embodiment of the mirror unit wherein one or more of the light extraction regions comprise a luminescent material (i.e. phosphor) arranged to convert at least part of the light from at least one of the one or more light sources into mirror unit light having another wavelength than the light from the at least one of the one or more light sources. The light source(s) may in general provide UV and/or blue light, and the light extraction regions may comprise one or more luminescent materials that are chosen to be able to convert at least part of the light from the light source into for instance one or more of blue-green, green, green-yellow, yellow, orange and red light. In the case that the light source provides UV light, the luminescent material may also be chosen so as to be able to provide blue light. In this way, a luminescent array of light extraction regions may be provided. Further, the light extraction regions may emit light, i.e. mirror unit light, wherein the mirror unit light may have spectral properties that vary from light extraction point to light extraction point.

The array of light extraction regions may for instance be a regular array or an irregular array or a combination thereof In a specific embodiment, the lighting unit is arranged to provide general lighting using at least part of the mirror unit light. This particularly implies that part or all of the light generated by the lighting unit is used to illuminate at least part of the space in front of the mirror unit front. This may be “direct” lighting, but in an embodiment also part of the light generated by the lighting unit may be directed in directions away from a normal to the mirror surface. In the latter embodiment, the mirror unit may be arranged to allow, when the lighting unit is switched on, light to be reflected by one or more of a wall, a floor and a ceiling. Assuming the mirror unit is arranged so as to be usable as a mirror for a user, the normal to the mirror surface is a normal which intercepts a person in front of the mirror surface observing himself/herself. The phrase “to illuminate at least part of the space in front of the mirror” particularly indicates embodiments in which the light is directed at a normal angle to the mirror surface in the range of 0-90°.

In a specific embodiment, the mirror unit is arranged to provide at least part of the general lighting in a direction intersecting a normal to the mirror surface. In such an embodiment, the mirror unit may be used to illuminate an observer in front of the mirror surface, i.e. an observer in (part of) the space in front the mirror surface. For instance, such a mirror unit may particularly be applied as fitting room mirror. Hence, in a specific embodiment, a fitting room mirror is provided comprising a mirror unit front comprising a mirror surface and a lighting unit comprising a plurality of light sources and a lenticular lens array arranged to provide mirror unit light in a space in front of the mirror unit front.

In a further embodiment, the mirror unit is arranged to provide at least part of the general lighting in a direction making an angle in the range of 65-90° with a normal to the mirror surface. Such angles may be chosen such as to illuminate the walls, ceiling and floor, but do not shine directly into the eyes of the person in front of the mirror. When light in these directions is provided, such light may especially be used as general lighting.

Note that the mirror, or more particularly the mirror surface, is not necessarily flat. It may also be curved or have other shapes. Preferably, however, the mirror surface is substantially flat. In substantially flat embodiments, the angle of a ray relative to a normal substantially is an angle relative to any normal to the mirror surface.

In yet a further embodiment, the mirror unit may be arranged to emit light in a direction away from the mirror surface, such as to a wall behind the mirror unit, said light being referred to as “ambient light”. Ambient light may especially relate to light that travels at angles with respect to the normal to the mirror surface in the range of larger than 90° up to and including 180°.

In a particularly preferred embodiment, the lighting unit is arranged to generate a 3D image using at least part of the mirror unit light. In this way, especially a mirror may be provided with attractive features. Even more preferably, the lighting unit is arranged to generate a 3D image containing symbols, especially information, using at least part of the mirror unit light. The symbols, or especially information, may in an embodiment relate to one or more of a trademark, commercial information, such as pricing information, news information, housekeeping rules, etc. The term “3D image” may relate to one or more 3D images.

The mirror unit may be arranged to provide a predetermined 3D image, i.e. the mirror may provide a 3D image whose content can in principle not be changed. However, in an embodiment, the content may also be variable, for instance by a user. In the latter embodiment, a kind of display is provided, i.e. a mirror unit comprising a 3D display unit.

It is known in the art how to generate 3D images using lenticular lenses. It is for instance referred to S. Hentschke et. al, SID, Sep. 18-21, 2006 Kent State University, OH, USA, Topic P 17, or M.P.C.M. Krijn et al, Journal of the SID 16/8 (2008), 847-855, or C. van Berkel et al, SPIE vol. 2653, 32-39 .

In yet a further embodiment, the invention provides a mirror unit, wherein the lighting unit is further arranged to generate a 3D virtual switch using at least part of the mirror unit light, wherein the mirror unit further comprises an approach sensor and a controller, wherein the lighting unit and the approach sensor are arranged to provide a sensor signal when the approach sensor is approached within a predetermined distance from the 3D virtual switch, and wherein the controller is arranged to control one or more parameters selected from the group consisting of a lighting parameter of the mirror unit light provided by the mirror unit, a display parameter of information displayed by the mirror unit, and space conditions of the space wherein the mirror unit is arranged. Especially in this way, a visible (“tangible”) and intuitive user interface may be provided, wherein the user, such as a person in a fitting room or in a (full) bathroom, etc., may manipulate predetermined parameters, such as lighting and/or information which is (especially) provided by the mirror unit, and/or space conditions, such as one or more of temperature, music, ventilation, etc., which may be provided by other apparatus to the space wherein the mirror unit is arranged, and optionally also other parameters.

The mirror unit according to the invention may further comprise a bezel, in which, in an embodiment, the lighting unit is integrated. An advantage of the lighting system of the invention may be that it may provide a relatively thin mirror unit (and thus also a relatively thin bezel). For instance, the mirror unit may, in an embodiment, have the same thickness as the mirror. In yet another embodiment, the bezel is slightly thicker than the mirror, for instance about 1-10 mm thicker than the mirror.

In a specific embodiment, the bezel is transparent, and at least part of the mirror unit light is provided through the bezel to the space in front of the mirror unit front. In a further embodiment, the mirror surface is arranged to be semi-transparent (such as a two-way mirror), and at least part of the mirror unit light is provided through the mirror surface to the space in front of the mirror unit front. In such embodiments, substantially the whole mirror front face may be the mirror surface. In an embodiment, the bezel comprises a two-way mirror, arranged to allow at least part of the light of the lighting unit to pass through the two-way mirror to the space in front of the mirror.

Therefore, the invention also provides the use of the herein described mirror unit as fitting room mirror. The mirror unit may also be used as grooming room mirror or grooming area mirror, or as (full) bath room mirror, as hallway or stairway mirror, etc. The mirror unit may further be used to display information by at least part of the mirror unit light.

The light generated as general lighting by the lighting unit is preferably white light, whereas the ambient light may be of any color. The light generated to provide a 3D image may also be of any color. The color(s) of the ambient light and/or the color(s) of the 3D image may also change with time, for instance determined by the user via the virtual 3D switch(es). The colors may for instance be blue, green, yellow or red, etc. (see also above).

The term “light” herein especially relates to visible light, i.e. light having a wavelength in the range of about 380-780 nm. The term white light as used herein, is known to the person skilled in the art. It especially relates to light having a correlated color temperature between about 2,000 and 20,000 K, especially 2700-20,000 K, for general lighting especially in the range of about 2700 K and 6500 K, and for backlighting purposes especially in the range of about 7,000 K and 20,000 K, and especially within about 15 SDCM (standard deviation of color matching) from the BBL (black body locus), especially within about 10 SDCM from the BBL, even more especially within about 5 SDCM from the BBL. The term “predetermined color” may relate to any color within the color triangle, but may especially refer to white light.

In the embodiments described herein use is made of amongst others terms like “arranged to provide light”, “arranged to generate a 3D”, and “arranged to provide general lighting”, and similar terms. These terms are especially used to indicate that the mirror unit in a “switched on” state is able to provide the described features. For the sake of clarity, the embodiments are often described in an “operational state”. The embodiments described herein and the embodiments claimed in the claims are not limited to mirror units that provide the described light, but also include such mirror units that are “switched off”.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIGS. 1a-1d schematically depict some embodiments of the mirror unit according to the invention;

FIGS. 2a-2b schematically depict some embodiments of the lighting unit according to the invention, wherein the lighting unit may be arranged to generate 3D images;

FIGS. 3a-3b schematically depict some further embodiments of the mirror unit according to the invention; and

FIG. 4 schematically depicts an embodiment of the lighting unit according to the invention.

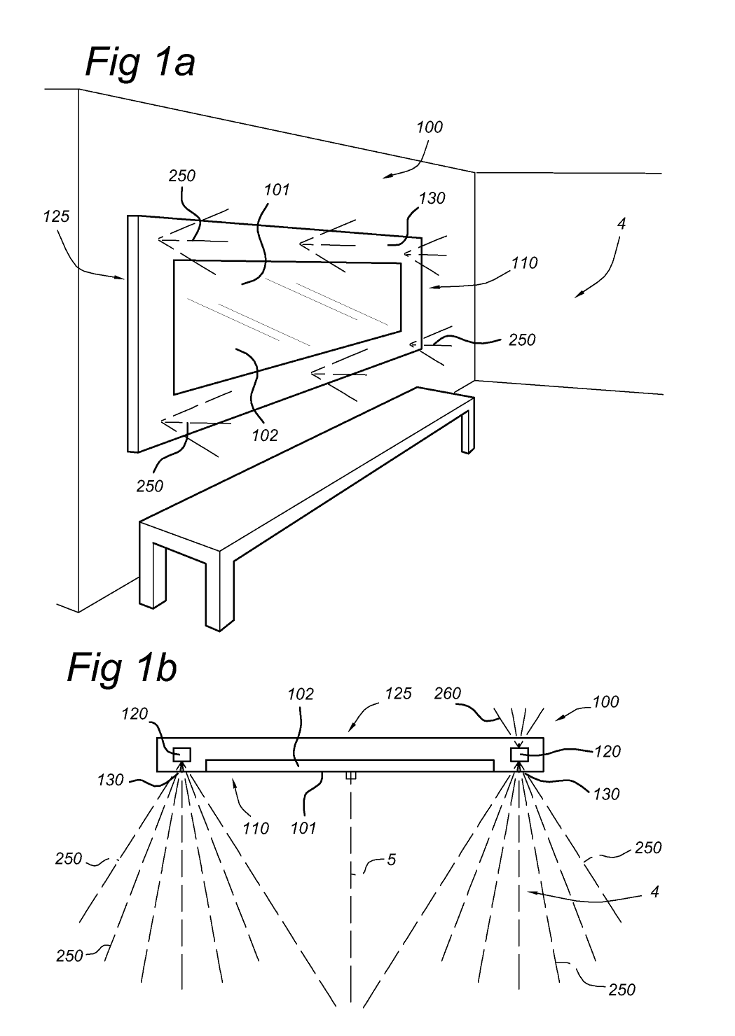

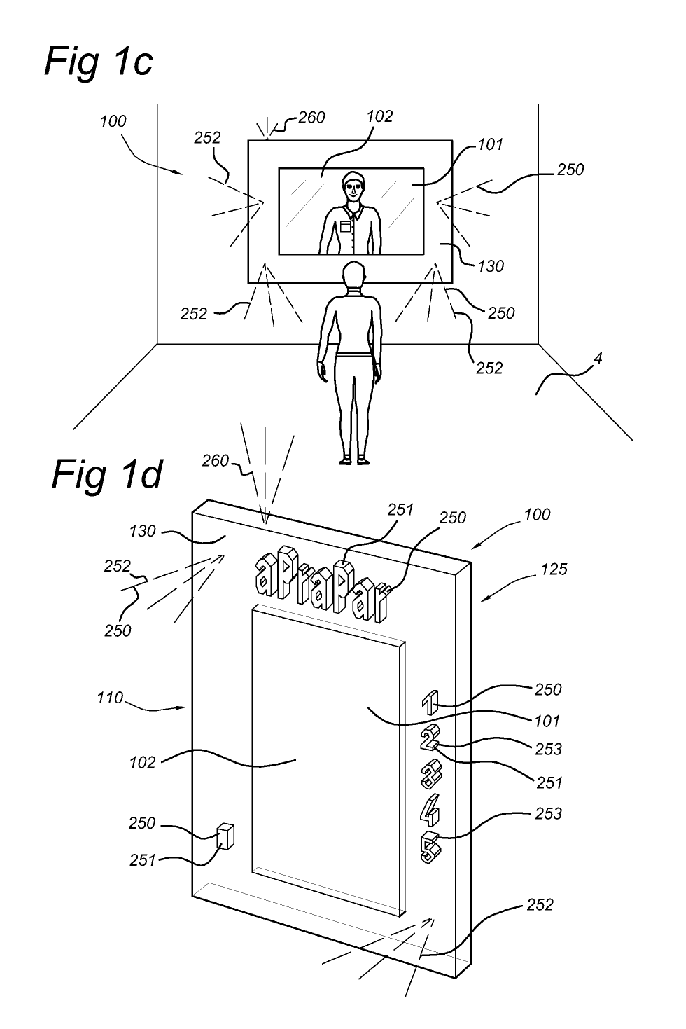

### DESCRIPTION OF PREFERRED EMBODIMENTS FIG. 1a schematically depicts a mirror unit 100 comprising a mirror 102.

The mirror 102, and thus the mirror unit 100, comprises a mirror surface 101. This mirror surface is arranged at the mirror unit front 110.

The mirror unit 102 further comprises a lighting unit 120, but in this schematic drawing, the lighting unit 120 is not drawn. Lighting unit 120 is arranged to provide mirror unit light 250 (when the mirror unit 100, or more accurately the lighting unit 120 thereof, is in a “switched on” state), further also referred to as “mirror light”. Light 250 is schematically indicated in FIG. 1a.

The mirror unit 100 can be arranged in a space, either indoors or outdoors. In front of the mirror unit front 100, when arranged as mirror unit 100, there is a space, indicated by means of reference 4.

In this way, an embodiment of a mirror unit 100 is provided, comprising:

a. the mirror unit front 110 comprising the mirror surface 101; and

b. the lighting unit 120 comprising a plurality of light sources 200 (not depicted; see below) and a lenticular lens array 300 (not depicted; see below) arranged to provide mirror unit light 250 in the space 4 in front of the mirror unit front 110.

By way of example, FIG. 1a shows an embodiment of the mirror unit 100 arranged at a wall in a room, and over a table, such as a make-up table.

In the schematic drawing, the mirror unit 100 further comprises, by way of example, a bezel 130, which may surround the mirror surface 101. A bezel 130 may also be obtained by arranging the mirror 102 on a support having a length and/or width larger than the mirror 102.

While FIG. 1a schematically shows an embodiment in perspective, FIG. 1b schematically depicts an embodiment of the mirror unit 100 in cross-section. The mirror unit 120 here comprises the front 110 and a back 125. The bezel 130 here surrounds the mirror 102. Further, optionally, the lighting unit 120 is in this embodiment also arranged to provide ambient light 260, which is (primarily) not directed to the space 4 in front of the mirror front 110.

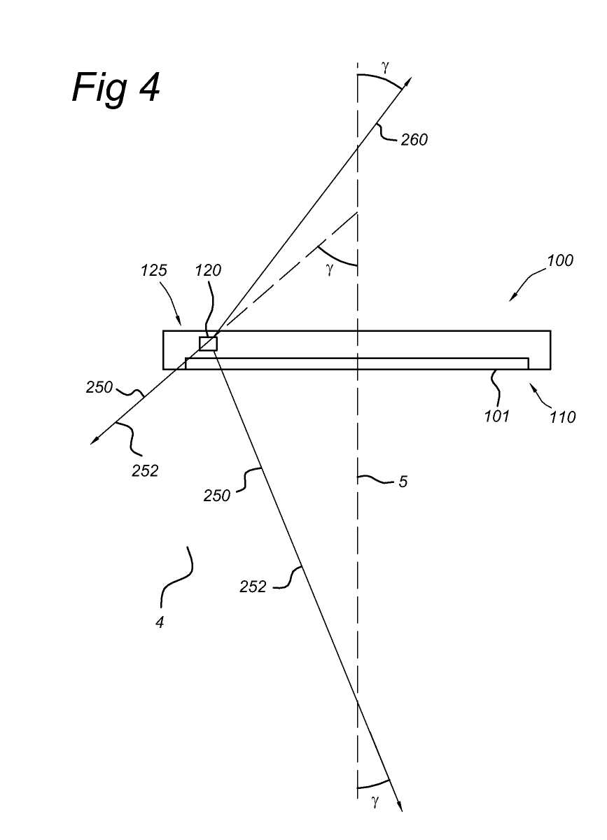

Further, FIG. 1b schematically shows a normal 5 to the mirror surface 101. The normal 5 is arbitrarily arranged. For illumination of a person in front of the mirror surface 101, at least part of the mirror light 250 will preferably make an angle with the normal in the range of 0-90°, see also below at FIG. 4, as schematically depicted in this Figure.

FIG. 1c schematically depicts a further embodiment with more details. The mirror unit 100 in this Figure is arranged to provide general lighting, indicated by means of reference 252 emitting at least part of the mirror light. Part of this general lighting 252 may be emitted sideways, such as at an angle with the normal in the range of about 65-90°. Such mirror light 250 may be used to illuminate a wall and/or a floor and/or a ceiling, thereby providing general light indirectly. Part of the mirror light 250 may be emitted at smaller angles, and may especially be used to directly illuminate objects or persons, etc. arranged in front of the mirror surface 101. Further, the mirror unit 100, more accurately the lighting unit 120 (not depicted), may also be arranged to provide ambient light 260. The color of general lighting 252 will in general be white, whereas the ambient light 260 may optionally also be colored.

FIG. 1d schematically depicts an embodiment wherein the mirror unit 100, especially the lighting unit 120, is further arranged to generate a 3D image 251, using at least part of the mirror unit light 250. In an embodiment, as schematically depicted in FIG. 1d, the lighting unit 120 is arranged to generate a 3D image 251 containing symbols, especially information, using at least part of the mirror unit light 250. For instance, a trademark may be displayed as (a) 3D symbol(s).

In a preferred embodiment, the lighting unit 120 is further arranged to generate a 3D virtual switch 253, using at least part of the mirror unit light 250. FIG. 1d schematically shows 4 virtual switches (1-4) depicted as numbers. Instead of the term “switch”, the term “button” may be applied. A virtual button or switch may particularly be a visible device to control electronics, which visible device does not necessarily have to be touched to be activated, but which is activated by an object (here including (part of) a human) approaching the location where the virtual button or switch is visible. Especially, the mirror unit 100 further comprises an approach sensor 40 and a controller 50 (not depicted), wherein the lighting unit 120 and the approach sensor 40 are arranged to provide a sensor signal when the approach sensor 40 is approached (by an object, for example a hand or a finger) within a predetermined distance from the 3D virtual switch 253, such as within about 0-10 mm. The controller 50 is arranged to control, in response to the sensor signal, one or more parameters selected from the group consisting of a lighting parameter of the mirror unit light 250 provided by the mirror unit 100, a display parameter of information displayed by the mirror unit 100, and space conditions of the space 4 wherein the mirror unit 100 is arranged. Especially in this way, a visible (“tangible”) and intuitive user interface may be provided, wherein the user, such as a person in a fitting room or in a (full) bathroom, etc., may manipulate predetermined parameters, such as lighting (like intensity and/or color of the general lighting and/or ambient lighting, respectively) and/or information which is (especially) provided by the mirror unit, and/or space conditions, such as one or more of temperature, music, ventilation, etc., which may be provided by other apparatus to the space wherein the mirror unit is arranged, and optionally also other parameters. Figure ld schematically depicts an example of an embodiment of the mirror unit wherein the lighting unit is arranged to generate 3D image(s) 251, 3D virtual switch(es) 253, and general lighting 252 by means of light 250.

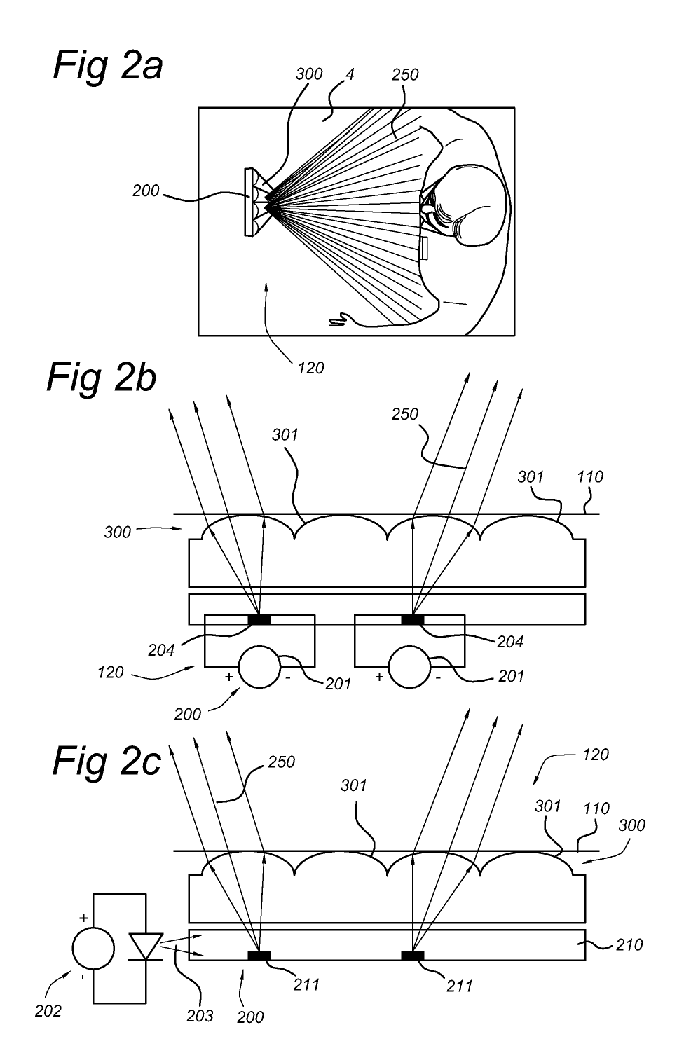

FIGS. 2a-2c further schematically depict embodiments of lenticular lens arrays 300 and the light sources 200, which can be used in the lighting unit to direct light, such as general lighting, and/or to provide 3D images. FIG. 2a shows how a 3D image may be generated using a plurality of light sources 200 and a lenticular lens array 300. This is known in the art. FIGS. 2b and 2c schematically depict two specific embodiments of the lighting unit 120. FIG. 2b schematically depicts an embodiment of a patterned OLED device, where for instance a light emitting pattern can be obtained by ink-jet printing. In an embodiment, the lighting unit 120 may be arranged to provide various light patterns, which may be switched on and off independently from one another. This may for instance be performed by using the 3D virtual switch(es) 253. In FIG. 2b, OLEDs 201 are depicted as well as lenticular lens array 300. The OLEDs 201 generate OLED light 204, and the OLEDs 201 and lenticular lens array 300 may be arranged to generate, from OLED light 204, general light travelling in a specific direction or in specific directions and/or a 3D image. Hence, in this embodiment, the plurality of light sources 200 especially comprise a plurality of OLEDs 201.

In yet another embodiment, as schematically depicted in FIG. 2c, a light guide 210 and a light source 202 are provided. The term “a light source” may also refer to a plurality of light sources. In this embodiment, the one or more light sources 202 are arranged to emit light 203 into the light guide 210. The light guide 210 may for instance be a polymeric light guide, but may also comprise glass or another material. The light guide 210 especially comprises a plurality of light extraction regions 211, such as predetermined irregularities at the interface of the light guide 210 and its exterior. The one or more light sources 202, the light guide 210, the plurality of light extraction regions 211, and the lenticular lens array 300 are arranged to provide mirror unit light 250 in the space 4 in front of the mirror unit front 110. Hence, the one or more light sources 202, the light guide 210, the plurality of light extraction regions 211, and the lenticular lens array 300 are arranged to provide general light travelling in a specific direction or in specific directions and/or a 3D image. In an embodiment, the light extraction regions 211 comprise luminescent material dots.

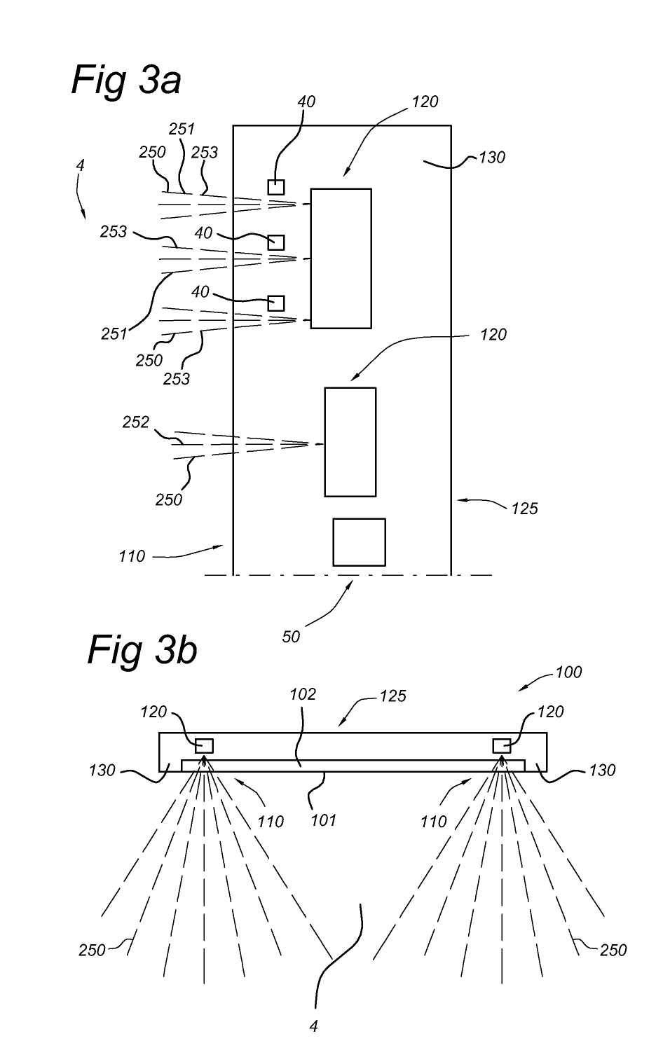

The lighting unit 120 is particularly integrated in the mirror unit 100. Part of the lighting unit 120 may be arranged behind the mirror 2, but in particular when bezel 130 is comprised by the mirror unit 100, the lighting unit 120 may at least partly be integrated in the bezel 130. FIG. 3a schematically depicts an embodiment wherein the lighting unit 120 is integrated in the bezel 130. FIG. 3a schematically depicts a cross section of an embodiment of the bezel 130.

In FIG. 3a, two lighting units 120 are schematically depicted. The upper one is for example arranged to provide 3D images 251, in particular virtual 3D switches 253, using mirror light 250. Further, in this embodiment, the mirror unit 100, here in particular the bezel 130, comprises one or more approach sensors 40, arranged to provide a sensor signal when the approach sensor(s) is (are) approached. Each virtual 3D switch 253 may be accompanied by such an approach sensor 40. The lower lighting unit 120 is for example arranged to provide general lighting 252 using mirror light 250. Further, a controller 50, also included in the bezel 130, is schematically depicted. This controller 50 is arranged to receive a sensor signal and thereby control for instance the intensity and/or color of the general lighting 252, etc.

The bezel 130 may be transparent, at least at those positions where mirror light 250 has to escape from the bezel 130, but the bezel 130 may also comprise openings through which mirror light may propagate to the space 4 in front of the mirror unit front 110. Hence, in an embodiment, the bezel 130 is transparent and at least part of the mirror unit light 250 is provided through the bezel 130 to the space 4 in front of the mirror unit front 110.

FIG. 3b schematically depicts (in cross section) an embodiment wherein the mirror surface 101 is arranged so as to be semi-transparent (i.e. at least part of mirror 102 is semi-transparent), and wherein at least part of the mirror unit light 250 is emitted through the mirror surface 101 to the space 4 in front of the mirror unit front 110. An advantage thereof is that a bezel 130 is not necessary to host the lighting unit 120. Even, the bezel 130 may be absent, which may be desired for esthetical reasons. The embodiment schematically depicted in FIG. 3b comprises an embodiment of the bezel 130.

FIG. 4 schematically depicts an embodiment of the mirror unit 100 according to the invention. Light 250 is emitted in different directions. The left ray travels in space 4 in a direction away from the normal 5. The right ray travels in space 4 in a direction intersecting the normal 5 to the mirror surface 101. The angle of light 250 with respect to the normal 5 is indicated by means of propagation angle γ. The left ray has for example a propagation angle γ of about 45°. The right ray has a propagation angle γ of about 25° . At angles equal to or larger than about 65° and equal to or preferably smaller than about 90° indirect general lighting may be achieved. Light having a propagation angle γ smaller than about 65° may be used as direct general lighting. Further, in the schematic drawing, light travelling in another direction is provided, which may be indicated as ambient light, and which may have a propagation angle with respect to the normal 5 in the range of larger than 90° and equal to or smaller than 180°.

The term “substantially” used herein, such as in “substantially perpendicular” or in “substantially consists”, will be understood by the person skilled in the art. The term “substantially” may also include embodiments with “entirely”, “completely”, “all”, etc. Hence, in embodiments the adjective substantially may also be removed. Where applicable, the term “substantially” may also relate to 90% or higher, such as 95% or higher, especially 99% or higher, even more especially 99.5% or higher, including 100%. The term “comprise” includes also embodiments wherein the term “comprises” means “consists of”. Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices employed herein are amongst others described during operation. As will be clear to the person skilled in the art, the invention is not limited to methods of operation or devices in operation.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “to comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. A mirror unit comprising:
a mirror unit front comprising a mirror surface;
a lighting unit comprising a plurality of light sources and a lenticular lens array arranged to provide mirror unit light in a space in front of the mirror unit front, wherein the plurality of light sources comprise a plurality of solid-state LEDs or OLEDs.

2. (canceled)

3. The mirror unit according to claim 1, wherein the lighting unit further comprises a light guide wherein the plurality of light sources are arranged to emit light into the light guide, wherein the light guide comprises a plurality of light extraction regions, and wherein the one or more light sources, the light guide, the plurality of light extraction regions, and the lenticular lens array are arranged to provide mirror unit light in the space in front of the mirror unit front.

4. The mirror unit according to claim 3, wherein one or more of the plurality of light extraction regions comprise a luminescent material arranged to convert at least part of the light from at least one of the one or more light sources into mirror unit light having another wavelength than the light from the at least one of the one or more light sources.

5. The mirror unit according to claim 1, wherein the lighting unit is arranged to provide general lighting using at least part of the mirror unit light.

6. The mirror unit according to claim 5, wherein the mirror unit is arranged to provide at least part of the general lighting in a direction intersecting a normal to the mirror surface.

7. The mirror unit according to claim 5, wherein the mirror unit is arranged to provide at least part of the general lighting in a direction making an angle in the range of 65 to 90° with a normal to the mirror surface.

8. The mirror unit according to claim 1, wherein the lighting unit is arranged to generate a 3D image using at least part of the mirror unit light.

9. The mirror unit according to claim 1, wherein the lighting unit is arranged to generate a 3D image containing symbols, especially information, using at least part of the mirror unit light

10. The mirror unit according to claim 1 wherein the lighting unit is further arranged to generate a 3D virtual switch using at least part of the mirror unit light , wherein the mirror unit further comprises an approach sensor and a controller, wherein the lighting unit and the approach sensor are arranged to provide a sensor signal when the approach sensor is approached within a predetermined distance from the 3D virtual switch , and wherein the controller is arranged to control, in response to the sensor signal, one or more parameters selected from the group consisting of a lighting parameter of the mirror unit light provided by the mirror unit, a display parameter of information displayed by the mirror unit, and space conditions of the space in which the mirror unit is arranged.

11. The mirror unit according to claim 1, further comprising a bezel, wherein the lighting unit is integrated in the bezel.

12. The mirror unit according to claim 1, further comprising a bezel, wherein the bezel his transparent, and wherein at least part of the mirror unit light is provided through the bezel to the space in front of the mirror unit front.

13. The mirror unit according to claim 1 wherein the mirror surface is arranged to be semi-transparent, and wherein at least part of the mirror unit light is provided through the mirror surface to the space in front of the mirror unit front.

14-15. (canceled)
